(19) United States
(12) Patent Application Publication
(10) Pub. No.: US 2026/0189045 A1
(43) Pub. Date: Jul. 2, 2026

(54) ELECTRONIC DEVICE, METHOD, AND NON-TRANSITORY STORAGE MEDIUM FOR MANAGING DEGRADATION DEGREE OF BATTERY

(71) Applicant: SAMSUNG ELECTRONICS CO., LTD., Suwon-si (KR)

(72) Inventors: Hyekyung JEON, Suwon-si (KR); Seungho LEE, Suwon-si (KR); Jaesung LEE, Suwon-si (KR); Chulhan KIM, Suwon-si (KR); Seunghoon OHN, Suwon-si (KR); Boyoung YU, Suwon-si (KR)

(73) Assignee: SAMSUNG ELECTRONICS CO., LTD., Suwon-si (KR)

(21) Appl. No.: 19/545,986

(22) Filed: Feb. 20, 2026

Related U.S. Application Data
(63) Continuation of application No. PCT/KR2024/012383, filed on Aug. 20, 2024.

(30) Foreign Application Priority Data
Aug. 21, 2023 (KR) 10-2023-0109414
Oct. 4, 2023 (KR) 10-2023-0131963

(51) Int. Cl. H02J 7/84; G01R 31/371; G01R 31/374; G01R 31/3842; G01R 31/392; H02J 7/90; H02J 7/96; H04R 1/1025

(52) U.S. Cl. CPC H02J 7/84; G01R 31/371; G01R 31/374; G01R 31/3842; G01R 31/392; H02J 7/96; H02J 7/977; H04R 1/1025

(57) ABSTRACT

An electronic device includes a battery, communication circuitry, at least one processor, and memory storing instructions. The instructions, when executed by the at least one processor individually or collectively, cause the electronic device to obtain connection information indicating a connection with a first external electronic device that provides power to charge the battery, based on charging of the battery being started, obtain charging start state information and store the charging start state information, based on the charging of the battery reaching an end state, obtain charging end state information and store the charging end state information, identify, based on the charging start state information and the charging end state information, a state of the battery, perform, based on the state of the battery, a battery degradation level measurement operation, and perform, based on a result of the battery degradation level measurement operation, a compensation operation during charging of the battery.

### CROSS-REFERENCE TO RELATED APPLICATIONS

This application is a continuation application of International Application No. PCT/KR2024/012383, filed on Aug. 20, 2024, which claims priority to Korean Patent Application No. 10-2023-0109414, filed on Aug. 21, 2023, and to Korean Patent Application No. 10-2023-0131963, filed on Oct. 4, 2023, in the Korean Intellectual Property Office, the disclosures of which are incorporated by reference herein in their entireties.

### BACKGROUND

### 1. Field

The present disclosure relates generally to batteries, and more particularly, to an electronic device, a method, and a non-transitory storage medium for managing the degradation level of a battery.

### 2. Description of Related Art

Recent advances in digital technology may provide for electronic devices to be offered in various forms such as, but not limited to, smartphones, tablet personal computers (PCs), personal digital assistants (PDAs), or the like. In addition, electronic devices that may worn by users in order to potentially enhance portability and/or user accessibility.

Various services and/or additional functions that may be provided by the electronic devices may also be gradually expanding and/or diversifying. That is, electronic devices may be continuously being developed to potentially enhance the utility of the electronic devices and to attempt to satisfy diverse needs of users.

As electronic devices evolve in various forms, the electronic devices may be connected to various types of external electronic devices to provide functions and/or information that may not be offered by the electronic devices. Furthermore, the electronic device may allow the external electronic devices to perform some of functions of the electronic devices, and/or may receive various pieces of information through networks, or the like.

Compensation for battery degradation in an electronic device containing a small battery may be provided to potentially compensate for battery degradation over a charge-discharge cycle during which the battery may be in use.

For example, at the start of charging a battery of an electronic device, the charge-discharge cycle of the battery may be checked, and a long-life algorithm operation based on the charge-discharge cycle may be performed. The long-life algorithm may set margins on charging-related parameters according to the predicted level battery degradation by modifying the full-charge voltage, the auxiliary charge voltage, and the open circuit voltage (OCV) table.

An electronic device may reflect the lifespan related to the charge/discharge cycles of a small-capacity, high-resistance coin battery. Thus, the lifespan under storage conditions (e.g., temperature, state of charge (SOC), or the like) having a significant impact may not reflected. Generally, in relation to the degradation level and lifespan of a battery, charge/discharge capacity and lifespan may be measured and compensated for through FuelGauge™ monitoring. However, while a relatively large-capacity battery may be monitored in real-time by a FuelGauge™ integrated circuit (IC), an electronic device having a relatively small-capacity battery (e.g., approximately 60 mAh or less, such as, but not limited to, an earbud) may face difficulties in real-time battery monitoring. For example, the real-time monitoring by the FuelGauge™ IC may significantly reduce usage time due to the relatively small total capacity of the battery.

Battery degradation may be divided into degradation due to the charge-discharge cycles during battery use and degradation due to storage conditions. An electronic device may compensate for the degradation by calculating the SOC only in the power-on state, and reflecting only the charge-discharge cycles during battery usage. However, a gap may exist between the actual battery degradation level and the number of charge-discharge cycles. In addition, increased battery resistance may prevent reaching the full-charge voltage, thereby potentially causing battery damage incidents.

### SUMMARY

One or more example embodiments of the present disclosure provide an electronic device, a method, and a non-transitory storage medium for managing the level of battery degradation in electronic devices (e.g., earbuds, smart rings, or the like) with small-capacity batteries for which real-time monitoring may be difficult, when compared to related electronic devices.

According to an aspect of the present disclosure, an electronic device includes a battery, communication circuitry, at least one processor, and memory storing instructions. The instructions, when executed by the at least one processor individually or collectively, cause the electronic device to obtain connection information indicating a connection with a first external electronic device that provides power to charge the battery, based on charging of the battery being started with the power applied from the first external electronic device, obtain charging start state information and store the charging start state information in the memory, based on the charging of the battery reaching an end state, obtain charging end state information and store the charging end state information in the memory, identify, based on the charging start state information and the charging end state information, a state of the battery, perform, based on the state of the battery, a battery degradation level measurement operation, and perform, based on a result of the battery degradation level measurement operation, a compensation operation during charging of the battery.

According to an aspect of the present disclosure, an operation method of an electronic device includes obtaining connection information indicating a connection with a first external electronic device that provides power to charge a battery of the electronic device, based on charging of the battery being started with the power applied from the first external electronic device, obtaining charging start state information and storing the charging start state information in a memory of the electronic device, based on the charging of the battery reaching an end state, obtaining charging end state information and storing the charging end state information in the memory, identifying, based on the charging start state information and the charging end state information, a battery state, performing, based on the battery state, a battery degradation level measurement, and performing, based on a result of the battery degradation level measurement, a compensation operation during charging of the battery.

According to an aspect of the present disclosure, a non-transitory storage medium storing one or more programs, wherein the one or more programs include instructions that, when executed by at least one processor of an electronic device, cause the electronic device to perform obtaining connection information indicating a connection with a first external electronic device that provides power to charge a battery of the electronic device, based on charging of the battery being started with the power applied from the first external electronic device, obtaining charging start state information and storing the charging start state information in memory of the electronic device, based on the charging of the battery reaching an end state, obtaining charging end state information and storing the charging end state information in the memory, identifying, based on the charging start state information and the charging end state information, a battery state, performing, based on the battery state, a battery degradation level measurement, and performing, based on a result of the battery degradation level measurement, a compensation operation during charging of the battery.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a block diagram of an electronic device within a network environment, according to various embodiments;

FIGS. 2A, 2B, and 2C illustrate examples of configurations of an electronic device and an external electronic device, according to an embodiment;

FIG. 3 is a block diagram illustrating the configuration of an electronic device, according to an embodiment;

FIG. 4 is a graph related to battery charging in the electronic device, according to an embodiment;

FIG. 5 is a flowchart illustrating an example of an operation method in an electronic device, according to an embodiment;

FIG. 6 is a flowchart illustrating an operation method in electronic device, according to an embodiment;

FIG. 7 is a flowchart illustrating an operation method in electronic device, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

The term “user” as used in the embodiments of the disclosure may refer to a person using an electronic device or a device using an electronic device (e.g., an artificial intelligence electronic device).

Hereinafter, various embodiments of the present disclosure are described with reference to the accompanying drawings.

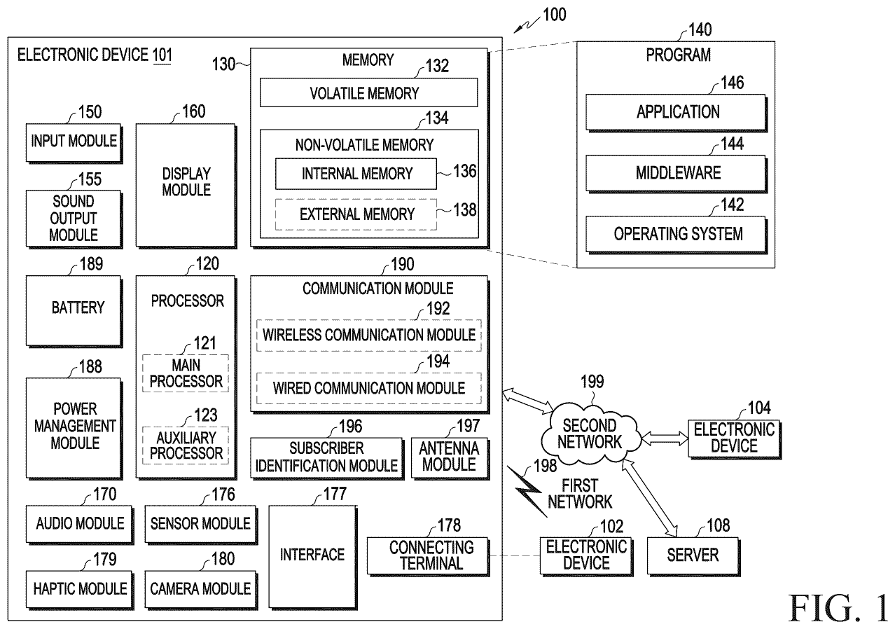

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

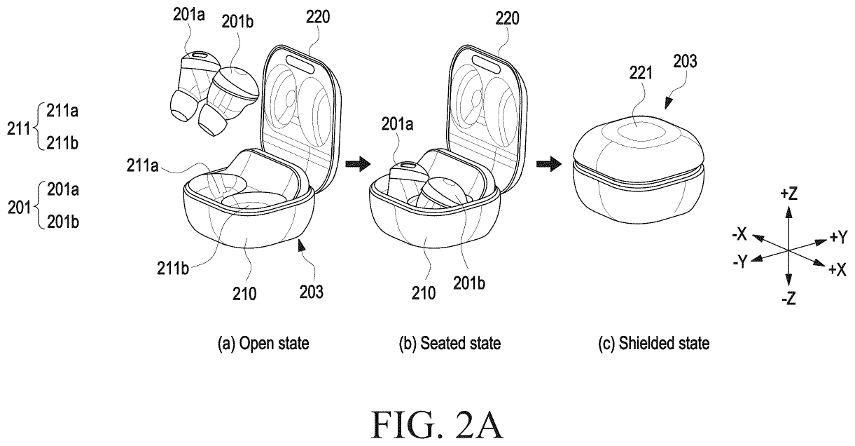

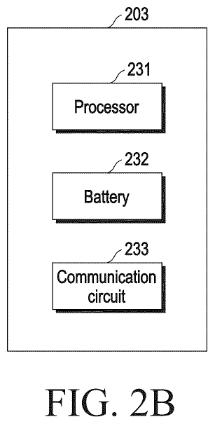

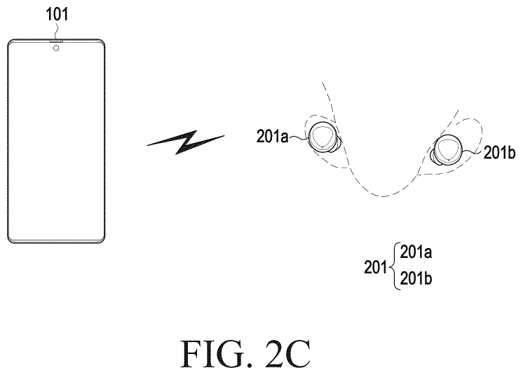

FIGS. 2A, 2B, and 2C illustrate examples of the configuration of an electronic device, according to an embodiment.

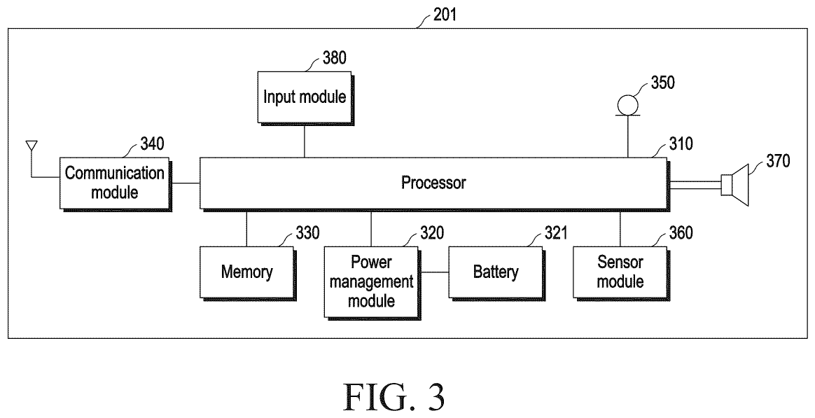

Referring to FIG. 2A, an electronic device 201, according to an embodiment, may be connected to an external electronic device (e.g., a first external electronic device 203) by using a wireless communication method and may charge a battery (e.g., a battery 321 shown in FIG. 3) with power (e.g., voltage and/or current) supplied from the first external electronic device 203. The electronic device 201, according to an embodiment, may be a wearable electronic device that may be worn on the body and includes a small-capacity battery (e.g., a coin battery, a cylindrical battery, or a pouch battery) based on true wireless stereo (TWS). According to an embodiment, the electronic device 201 may be stored in the first external electronic device 203, such as a cradle, which is a receiving device for charging and/or storage.

According to an embodiment, the electronic device 201 may be a wearable electronic device including at least one component related to acoustic effects (e.g., a speaker and a microphone) and may be worn in a location close to a user's ear, such as an in-ear earphone (or ear set) or a hearing aid. According to an embodiment, the electronic device 201 may be worn on a part of the body, such as the ear or head, and may be a wearable electronic device (e.g., a pair of earphones (or ear sets) and hearing aids, a headset, or speakers) that includes at least one component related to acoustic effects (e.g., speakers and microphones). For example, the electronic device 201 may be one of a pair of first electronic device 201a and second electronic device 201b that may be worn on the user's ears, respectively. The first electronic device 201a and second electronic device 201b may each be implemented as a left earphone and a right earphone that wirelessly output sound. For example, the electronic device 201 may be implemented as TWS-based wireless earphones. The electronic device 201, according to an embodiment described herein, is not limited to the TWS method and may be implemented as audio devices using methods other than the TWS method. For convenience of description, the electronic device 201, according to an embodiment, is described using the first electronic device 201a as an example. However, the electronic device 201 may be the second electronic device 201b, and the second electronic device 201b may have the same components and technical features as the first electronic device 201a, according to an embodiment.

Referring to FIG. 2A, the first external electronic device 203, according to an embodiment, may be a cradle device configured in the form of a case capable of storing the electronic device 201. Based on the electronic device 201 being mounted within an internal accommodation space 211, the first external electronic device 203 may be connected to the electronic device 201 in a wireless or wired manner, and may apply power for charging to the electronic device 201. The first external electronic device 203, according to an embodiment, may be connected to another external electronic device that supplies external power, and may transmit power supplied from the other external electronic device to the electronic device 201.

According to an embodiment, the first external electronic device 203 may be opened or closed, and the user may store the electronic device 201 (e.g., the first electronic device 201a and/or the second electronic device 201b) within a separate accommodation space 211. The accommodation space 211 may include a first accommodation space 211a and a second accommodation space 211b for accommodating the first electronic device 201a and the second electronic device 201b, respectively.

According to an embodiment, the first external electronic device 203 may include a first housing 210 and a second housing 220 disposed on top of the first housing 210 and capable of shielding at least a portion of the first housing 210. When the first housing 210 is shielded by the second housing 220, the separation of the electronic device 201 accommodated within the accommodation space 211 may be prevented. According to an embodiment, the first external electronic device 203 may be electrically connected to the electronic device 201 to supply power to the electronic device 201 or transmit or receive electrical signals. According to an embodiment, various electronic components may be arranged inside the first housing 210 and/or the second housing 220 of the first external electronic device 203. According to an embodiment, the first external electronic device 203 may include a display 221 in an area of the second housing 220 that is exposed to the outside, and may display, through the display 221, charging state information (e.g., battery charging start, charging in progress, or charging complete) and battery state information (e.g., information about battery damage or information related to battery lifespan) received from the electronic device 201.

According to an embodiment, the first external electronic device 203 may have an open state (a) and a shielded state (c). The open state may mean a state in which the second housing 220 does not shield the first housing 210, and the top (the +z-axis direction) of the first housing 210 is open. The shielded state may mean a state in which the second housing 220 shields the first housing 210. Furthermore, the seated state (b) may mean a state in which the electronic device 201 is placed within the first housing 210 (e.g., the accommodation space 211) in the open state. In the following description, the terms “open state,” “shielded state,” and “seated state” are used to describe the disclosure. It is to be understood that the first external electronic device 203 in the disclosure is not limited to devices related to the electronic device 201 and may equally apply to all types of devices for charging.

Referring to FIG. 2B, the first external electronic device 203, according to an embodiment, may include a processor 231 (e.g., the processor 120 in FIG. 1), a battery 232 (e.g., the battery 189 in FIG. 1), and communication circuitry 233 (e.g., the communication module 190 in FIG. 1) in order to wirelessly charge the electronic device 201. According to an embodiment, the first external electronic device 203 may further include power management circuitry (or module) that is connected to the battery 232 to manage power. The first external electronic device 203 may include a timer for measuring the full-charge time and/or the time to enter an auxiliary charge when charging the electronic device 201. According to an embodiment, the timer may be included in the electronic device 201. The first external electronic device 203 may further include other components for interworking with the electronic device 201.

Referring to FIG. 2C, the electronic device 201 (e.g., the electronic devices 201a or 201b), according to an embodiment, may be connected to a second external electronic device (e.g., the electronic device 101 in FIG. 1) by using a wireless communication method to perform wireless communication.

According to an embodiment, the electronic devices 201a and 201b may be arranged such that acoustic components (e.g., audio modules) and electronic components (e.g., processors) within the electronic devices 201a and 201b are positioned to enhance acoustic performance. According to an embodiment, the electronic devices 201a and 201b may function as audio output interfaces (or audio output modules) that output an audio signal received from the second external electronic device 101 to the outside. Additionally or alternatively, the electronic devices 201a and 201b disclosed in various embodiments herein may function as audio input interfaces (or input modules) for receiving audio signals corresponding to sounds obtained from the outside. According to an embodiment, each of the first electronic device 201a and the second electronic device 201b may convert data received from the second external electronic device 101 into sound and output the converted sound (e.g., audio, music, ambient sound, notification sound, or ringtones) through a speaker. Each of the first electronic device 201a and the second electronic device 201b may obtain external sound (e.g., the user's voice or ambient sound) through at least one microphone and transmit data corresponding to the obtained sound to the second external electronic device 101.

According to an embodiment, the electronic devices 201a and 201b may be wirelessly connected to the second external electronic device 101. For example, the electronic devices 201a and 201b may communicate with the second external electronic device 101 via a network (e.g., a short-range wireless communication network or a long-range wireless communication network). The network may include, but not limited to, a mobile or cellular communication network, a local area network (LAN) (e.g., Bluetooth™ communication, Bluetooth™ Low Energy communication), a wireless local area network (WLAN), a wide area network (WAN), the Internet, or a small-area network (SAN). According to an embodiment, the electronic device 201 may be wiredly connected to the second external electronic device 101 by using a cable.

For ease of description, the electronic device 201 described with reference to the drawings herein is described as being one of the first electronic device 201a and the second electronic device 201b. The technical features and components of the first electronic device 201a may be applied identically or similarly to the second electronic device 201b.

FIG. 3 is a block diagram illustrating the configuration of an electronic device, according to an embodiment.

Referring to FIG. 3, an electronic device 201 (e.g., the first electronic device 201a or the second electronic device 201b), according to an embodiment, may include a processor 310 (e.g., the processor 120 in FIG. 1), a power management module 320 (e.g., the power management module 188 in FIG. 1), a battery 321 (e.g., the battery 189 in FIG. 1), memory 330 (e.g., the memory 130 in FIG. 1), a communication module 340 (e.g., the communication module 190 in FIG. 1), at least one microphone 350 (e.g., the input module 150 in FIG. 1), a sensor module 360 (e.g., the sensor module 176 in FIG. 1) including at least one sensor, a speaker 370 (e.g., the sound output module 155 in FIG. 1) and/or an input module 380 (e.g., the input module 150 in FIG. 1). The term “module” for the components described in FIG. 3 may be replaced with “circuit.”

According to an embodiment, the processor 310 may be electrically or operatively connected to the power management module 320, the battery 321, the memory 330, the communication module 340, the at least one microphone 350, the sensor module 360 including at least one sensor, the speaker 370, and/or the input module 380, and may perform overall control operations of the electronic device 201.

According to an embodiment, the processor 310 may control the battery 321 that provides power for operating the electronic device 201. The processor 310 may manage charging and discharging of the battery 321 through the power management module 320. According to an embodiment, the processor 310 may include a voice processing circuit, and by the voice processing circuit, may perform control to process audio data received from the second external electronic device 101 and output an audio signal (e.g., an acoustic signal).

According to an embodiment, the processor 310 may identify that the electronic device 201 is accommodated in the accommodation space 211 of the first external electronic device 203 and connected to the first external electronic device 203, and may charge the battery 321 by using power applied from the battery 232 of the first external electronic device 203. Without limited thereto, when an external power source (e.g., TA, wireless charger, or D2D) is applied to the first external electronic device 203, the electronic device 201 may receive external power through the first external electronic device 203 to charge the battery 321. According to an embodiment, the processor 310 may monitor the charging voltage level of the battery 321 to determine whether the battery is fully charged. If the battery 321 is fully charged, the processor 310 may terminate charging. The processor 310 may transmit a control signal to the first external electronic device 203 via the communication module 340 to terminate charging. The processor 310 may monitor the auxiliary charge voltage of the battery 321 after full charge to determine whether auxiliary charging is required. If the monitored battery voltage level reaches an auxiliary charge voltage value, the processor 310 may control auxiliary charging of the battery 321 from the start of auxiliary charging until the battery reaches full charge. The processor 310 may transmit a control signal to the first external electronic device 203 via the communication module 340 to initiate auxiliary charging.

According to an embodiment, when charging of the battery 321 is started using power supplied from the first external electronic device 203 or the external power source applied to the first external electronic device 203, the processor 310 may obtain charging start state information and store the obtained charging start state information in the memory 330. Here, the charging start state information may include at least one of a voltage, a current, a state of charge (SOC), or a temperature at the start of charging the battery 321. Based on the electronic device 201 being accommodated in the accommodation space 211 inside the first housing 210 of the first external electronic device 203 and the second housing 220 being closed, the processor 310 may not perform wireless communication with the second external electronic device 101 when the battery 321 is charged by the first external electronic device 203, and may be connected to the second external electronic device 101 by using a wireless communication method (e.g., Bluetooth™ communication) after the charging of the battery 321 is ended (e.g., stopped or fully charged).

According to an embodiment, the processor 310 may obtain charging end state information, based on the end of charging of the battery 321 (e.g., charging stop or full charge), and store the obtained charging end state information in the memory 330. Here, the charging end state information may include at least one of a voltage, a current, a state of charge (SOC), or a temperature at the end of charging the battery 321.

According to an embodiment, after charging of the battery 321 is ended, the processor 310 may compare the charging start state information and the charging end state information stored in the memory 330 to identify the battery degradation level through a battery degradation level measurement operation (e.g., a battery degradation level algorithm). According to an embodiment, after charging of the battery 321 is ended, the processor 310 may compare the charging start state information and the charging end state information stored in the memory 330 to identify a battery state (e.g., normal state, battery damage (short) risk or reduced lifespan), and may then configure battery state information (e.g., current charge capacity information, charge capacity-based degradation stage values, or notification information to alert of battery damage (short) risk or reduced lifespan) regarding the identified battery state. Here, the processor 310 may, for example, configure notification information by using the charge capacity information or the degradation stage values, and control the communication module 340 to transmit the configured notification information to the first external electronic device 203 and/or the second external electronic device 101, as part of the battery state information or separately. In another example, the second external electronic device 101 may configure notification information based on the received battery state information and output (or display) the configured notification information. The processor 310 may perform a battery 321 degradation measurement operation while the electronic device 201 is accommodated in the accommodation space 211 inside the first housing 210 of the first external electronic device 203 and the second housing 220 is closed. When the electronic device 201 is accommodated in the accommodation space 211 inside the first housing 210 of the first external electronic device 203 and the second housing 220 is open, the processor 310 may identify that the user is using the electronic device 201 and may stop the battery 321 degradation measurement operation as power supply from the first external electronic device 203 is stopped. When some functions of the electronic device 201 are operating (in use), discharge of the battery occurs due to the functions in use, making accurate battery degradation level measurement difficult due to a constant current discharge operation. Therefore, the electronic device 201 may stop the battery 321 battery degradation level measurement operation when the first external electronic device 203 is open. According to an embodiment, in order to set compensation operations, the processor 310 may measure the actual degradation level of the battery 321 by using a constant current discharge operation within a specific interval after the battery 321 is fully charged. Based on the charging start state information and the charging end state information, the processor 310 may identify the degradation (e.g., aging) of the battery 321. If the degradation level is within a normal range (e.g., a range not identified as the time for battery replacement due to battery damage or reduced battery lifespan), the processor 310 may activate (on) a constant current function (e.g., a light-emitting diode (LED)) for a specified time (e.g., 5 seconds) by using the constant current discharge operation to measure the actual degradation level of the battery 321 caused by the constant current function.

According to an embodiment, when the processor 310 performs a battery degradation level measurement operation (e.g., before or during a constant current discharge operation after a full charge), the processor 310 may obtain a temperature change value by comparing a charging start temperature value included in the charging start state information with a charging end temperature value included in the charging end state information. When a state in which the temperature change value is greater than or equal to a first threshold (e.g., a first state) occurs a specified number of times (e.g., three times), the processor 310 may lower the full-charge voltage of the battery 321 to a specified value (−2.0V) and control the communication module 340 to transmit battery state information indicating the risk of battery 321 damage to at least one of the first external electronic device 203 or the second external electronic device 101. Here, when the battery 321 is in a damaged state, the processor 310 may lower the full-charge voltage to a specified value to reduce charging in the constant voltage (CV) range, thereby protecting the battery 321. According to an embodiment, when the state in which the temperature change value is greater than or equal to the first threshold occurs less than the specified number of times, the processor 310 may return to the previously set value. According to an embodiment, when the state in which the temperature change value is greater than or equal to the first threshold occurs less than the specified number of times, the processor 310 may obtain a voltage change value by comparing a charging start voltage value included in the charging start state information with a charging end voltage value included in the charging end state information. When a state in which the voltage change value is greater than or equal to a second threshold (e.g., a second state) occurs less than a specified number of times (e.g., three times), the processor 310 may measure the degradation level of the battery 321 through a constant current (CC) discharge operation. When the state in which the voltage change value is greater than or equal to the second threshold occurs the specified number of times, the processor 310 may store information related to battery lifespan reduction (e.g., an NV value), and control the communication module 340 to transmit battery state information indicating the risk of battery 321 damage or battery replacement guidance to at least one of the first external electronic device 203 or the second external electronic device 101.

According to an embodiment, the processor 310 may set compensation operations for battery degradation compensation according to degradation levels obtained by the battery degradation level measurement operation. The processor 310 may perform compensation for the resistance and voltage drop of the battery 321 based on the compensation operations that are set according to the obtained degradation levels. The processor 310 may set a first compensation operation not including compensation information, based on the degradation level being a first degradation level. The processor 310 may set a second compensation operation including first compensation information, based on the degradation level being a second degradation level (e.g., a level at which the electronic device 201 may be used without abnormality at a set full-charge voltage). Here, the first compensation information may include a first full-charge condition margin value (e.g., +30 mV). According to an embodiment, the processor 310 may set a third compensation operation including second compensation information, based on the degradation level being a third degradation level (e.g., a level sufficient to cause damage to the battery). Here, the second compensation information may include a second full-charge condition margin value (e.g., +50 mV) and a first voltage value (e.g., −0.1 V) for full-charge voltage drop. The full-charge voltage may be set to different values for each battery compensation charge level.

According to an embodiment, the processor 310 may perform compensation operations (e.g., a plurality of set compensation operations) for the battery 321 by using a compensation algorithm (e.g., a long-life algorithm) that applies compensation operations set for multiple degradation levels. For example, the processor 310 may identify a degradation level, based on state of charge (SOC) information measured during charging or auxiliary charging of the battery 321. When the identified degradation level is the first degradation level, the processor 310 may apply the first compensation operation. Since the first compensation operation does not include a compensation value, the battery 321's degradation level (e.g., capacity) may not be compensated for at the first degradation level. For example, when the identified degradation level is the second degradation level (e.g., a level at which the electronic device 201 may be used without abnormality at the set full-charge voltage), the processor 310 may compensate for the degradation level (e.g., capacity) of the battery 321 by applying the first full-charge condition margin value (e.g., +30 mV) included in the second compensation operation. For example, when the identified degradation level is the third degradation level (e.g., a level sufficient to cause damage to the battery), the processor 310 may compensate for the degradation level (e.g., capacity) of the battery 321 by applying the second full-charge condition margin value (e.g., +50mV) included in the third compensation operation and lowering the full-charge voltage to the first voltage value (e.g., −0.1 V).

According to an embodiment, the power management module 320 may efficiently manage and optimize the use of power from the battery 321 in the electronic device 201. According to an embodiment, the power management module 320 may adjust power supplied to the processor 310 based on a signal provided from the processor 310 corresponding to the load to be processed, or adjust power supplied to components (e.g., the memory, the communication module, the input module, and/or the sensor) other than the processor 310. According to an embodiment, the power management module 320 may include a battery charging module. According to an embodiment, the power management module 320 may wiredly or wirelessly receive power from the first external electronic device 203, which is an external power supply device, to charge the battery 321. According to an embodiment, the battery 321 may be charged with power applied from the first external electronic device 203. The battery voltage (capacity) of the battery 321 decreases over time due to natural discharge, and thus, when the voltage of the battery 321 drops to an auxiliary charge voltage, the battery 321 may be auxiliary-charged to a full-charge voltage by using power applied from the first external electronic device 203.

According to an embodiment, the memory 330 may store various pieces of data and/or information used by at least one component (e.g., the power management module 320, the battery 321, the memory 330, the communication module 340, the at least one microphone 350, the sensor module 360 including at least one sensor, the speaker 370, and/or the input module 380) of the electronic device 201. The data may include, for example, software (e.g., programs) and input or output data related to commands associated therewith. For example, the memory 330 may store instructions for performing operations of the electronic device 201 (or the processor 310). According to an embodiment, the memory 330 may store information related to charging and auxiliary charging of the battery 321. The memory 330 may store the charging start state information and the charging end state information of the battery 321, and may store information related to the set compensation operations of the compensation algorithm.

According to an embodiment, the electronic device 201 may provide a user interface related to the function of receiving audio data from the second external electronic device 101 or the function of transmitting audio data to the second external electronic device 101. For example, the user interface may include a light-emitting element (e.g., a constant current element or function) such as a light-emitting diode (LED). For example, the light-emitting element may be controlled to emit light in a color corresponding to charging in progress or charging complete. For instance, when the electronic device 201 is connected to the second external electronic device 101, the light-emitting element may be controlled by the processor 310 to emit light in a specific color.

According to an embodiment, the at least one microphone 350 may obtain sound signals when in an ON (e.g., activated or operating) state. When the electronic device 201 includes a plurality of microphones, at least one (e.g., an inner mic) of the plurality of microphones may be positioned near the inner part of the ear when the electronic device 201 is inserted into the ear, and at least one other microphone may be positioned on the outer part of the ear when the electronic device 201 is worn in the user's ear. The at least one microphone 350 may be turned on (e.g., activated or operating) or off (e.g., deactivated or non-operating) under the control of the processor 310. FIG. 3 depicts the electronic device 201 as including at least one microphone 350, but the technical idea of the disclosure is not limited thereto. For example, a plurality of microphones may be provided, the number of which is two, three, or more than three.

According to an embodiment, the sensor module 360 may include at least one sensor capable of measuring or detecting changes in the surrounding environment (e.g., vibration, movement, and/or sound). According to an embodiment, the sensor module 360 may include a voice pick-up (VPU) sensor. For example, the VPU sensor may include a multi-axis acceleration sensor (e.g., a 3-axis acceleration sensor, a 6-axis acceleration sensor, or another multi-axis acceleration sensor), and may detect a signal (e.g., a vibration signal, a motion signal, or a sound signal) transmitted through at least a portion of the user's body for each axis. For example, when a user utters a voice, vibrations of the user's vocal cords may be detected by the multi-axis acceleration sensor and obtained as signals related to at least some of multiple sounds associated with the voice signal. According to an embodiment, the multi-axis acceleration sensor may be controlled by the processor 310 to selectively activate or operate (e.g., turn on) at least some of the multiple axes. The technical idea of the disclosure may not be limited thereto, and may further include other sensors related to audio signal processing.

According to an embodiment, the speaker 370 may output an audio signal (e.g., a sound signal), based on control of the processor 310.

According to an embodiment, the input module 380 may be configured to generate various input signals required for operating (or controlling operation of) the electronic device 201. For example, the input module 380 may include a touchpad, a touch panel, or a button. The touchpad may recognize a touch input by using at least one of a capacitive type, a resistive type, an infrared type, or an ultrasonic type. When a capacitive touchpad is provided, physical contact or proximity recognition may be possible. The touchpad may further include a tactile layer. A touchpad including a tactile layer may provide tactile feedback to the user. The button may include, for example, a physical button and/or an optical key. For example, the input module 380 may generate an input signal based on a user input and transmit the input signal to the processor 310. For example, the user input may be associated with functions such as entering a call state, terminating a call state, volume adjustment, and/or muting.

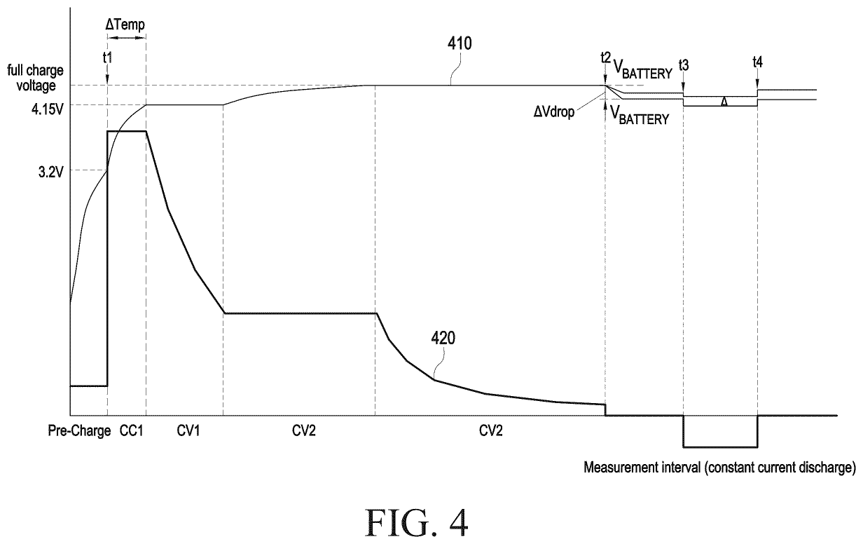

FIG. 4 is a graph related to battery charging in an electronic device, according to an embodiment.

According to an embodiment, the battery 321 of the electronic device 201 may undergo a reduction in a battery capacity characteristic over time. For example, the battery capacity characteristic may decrease (e.g., falls below approximately 4.3 V to approximately 4.4 V) at a full-charge voltage (e.g., approximately 4.3 V to approximately 4.4 V) and an auxiliary charge voltage (e.g., approximately 4.30 V) set for the battery 321 of the electronic device 201.

Referring to FIG. 4, according to an embodiment, the processor 310 may monitor the battery voltage (e.g., a first graph 410) for charging the battery 321 during a charge-discharge cycle (e.g., cc1, cv1, cc2, and cv2 intervals; t1-t2). Here, the charge-discharge cycle may be a time interval (e.g., a charging interval) from a charging start time point t1 of the battery 321 (t1) to a full-charge time point t2 of a full-charge voltage (e.g., approximately 4.3V to approximately 4.4V). A second graph 420 in FIG. 4 may represent a graph (e.g., constant current (CC)-constant voltage (CV)) showing the battery current value according to the battery charging operation during the charge-discharge cycle (t1-t2). The t1-t2 interval shown in FIG. 4 may represent a battery charging interval ranging from 0% to 100%. According to an embodiment, after full charge (time point t2), if the electronic device is accommodated in the first external electronic device 203 and the electronic device 201 is not in use while the first external electronic device 203 is in a closed state, the processor 310 may perform an actual battery degradation level measurement operation (e.g., a constant current discharge operation) during a t3-t4 interval (e.g., a measurement interval). When a discharge current flows during a t2-t4 interval shown in FIG. 4, a voltage drop may occur. In the first graph 410, an upper solid line is set as a reference for a fresh cell having little or no degradation, while a lower solid line indicates that the internal resistance has increased, resulting in a larger voltage drop (Vdrop) even under the same discharge current. The processor 310 may determine the level of degradation by using a delta value of the difference between the degraded battery's Vdrop and the fresh cell's Vdrop.

The electronic device 201, according to an embodiment, may implement a software module (e.g., the program 140 in FIG. 1) for battery charge management. The memory 330 of the electronic device 201 may store instructions (e.g., instructions) to implement the software module shown in FIG. 2. At least one processor 310 may execute the instructions stored in the memory 330 to implement the software module and may control hardware associated with the function of the software module. The software module of the electronic device 201, according to an embodiment, may be configured to include a kernel (or HAL), a framework (e.g., the middleware 144 in FIG. 1), and an application (e.g., the application 146 in FIG. 1). At least a portion of the software module may be preloaded on the electronic device 201 or downloadable from a server (e.g., the server 108). According to an embodiment, at least a portion of the software modules may be implemented as software, firmware, hardware, or a combination of at least two of these. At least a portion of the software module may be implemented (e.g., executed) by, for example, a processor (e.g., AP). At least a portion of the software module may include, for example, a module, a program, a routine, sets of instructions, or process for performing at least one function.

Thus, in an embodiment, the electronic device 201 in FIG. 3 was used to describe the main components of the electronic device. However, in various embodiments, not all components shown in FIG. 3 are essential components, the electronic device 201 may be implemented with more components than the illustrated components, or with fewer components than the illustrated components. Furthermore, the positions of the main components of the electronic device 201 described above with reference to FIG. 3 may be changed depending on various embodiments.

According to an embodiment, an electronic device (e.g., the electronic device 201 in FIGS. 2A, 2C, and FIG. 3) may include a battery (e.g., the battery 321 in FIG. 3), communication circuitry (e.g., the communication module 340 in FIG. 3), and at least one processor (e.g., the processor 310 in FIG. 3), and memory (e.g., the memory 330 in FIG. 3) configured to store instructions.

According to an embodiment, when executed by the at least one processor of the electronic device, the instructions may cause the electronic device to be connected to a first external electronic device (e.g., the first external electronic device 203 in FIGS. 2A and 2B) that provides power through the communication circuit.

According to an embodiment, the instructions may cause the electronic device to obtain charging start state information when charging of the battery is started with power applied from the first external electronic device, and store the charging start state information.

According to an embodiment, the instructions may cause the electronic device t obtain charging end state information, based on the end of charging of the battery, and to store the charging end state information.

According to an embodiment, the instructions may cause the electronic device t identify a battery state, based on the charging start state information and the charging end state information, and perform a battery degradation level measurement operation, based on information about the identified battery state.

According to an embodiment, the instructions may cause the electronic device t perform a compensation operation (e.g., a set compensation operation) to be applied during charging of the battery, based on information obtained by the battery degradation level measurement operation.

According to an embodiment, the electronic device may include an earbud, and the first external electronic device may include a case including an accommodation space (e.g., the accommodation space 211 in FIG. 2A) for storing the earbud, and a battery inside the case.

According to an embodiment, the instructions may cause the electronic device to identify the earbud accommodated in the accommodation space in the case, and perform the battery degradation level measurement operation, based on the earbud being accommodated in the accommodation space inside a first housing (e.g., the first housing 210 in FIG. 2A) of the case and a second housing (e.g., the second housing 220 in FIG. 2A) being closed with respect to the first housing.

According to an embodiment, the instructions may cause the electronic device to perform the battery degradation level measurement operation, based on at least one of a temperature change value, a voltage change value, or a constant current discharge operation, and stop the battery degradation level measurement operation, based on the earbud being accommodated in the accommodation space inside the first housing of the case and the second housing being opened with respect to the first housing.

According to an embodiment, the battery degradation level measurement operation may be performed by obtaining the temperature change value by comparing a charging start temperature value included in the charging start state information with a charging end temperature value included in the charging end state information. The compensation operation may be performed by lowering the full-charge voltage level of the battery to a specified value, based on a state in which the temperature change value is greater than or equal to a first threshold occurring a specified number of times (e.g., three times).

According to an embodiment, the instructions may cause the electronic device to control the communication circuitry to transmit notification information indicating a risk related to the battery to at least one of the first external electronic device or a second external electronic device, based on the state in which the temperature change value is greater than or equal to the first threshold occurring the specified number of times.

According to an embodiment, the battery degradation level measurement operation may be performed by, based on the state in which the temperature change value is greater than or equal to the first threshold occurring less than the specified number of times, obtaining a voltage change value by comparing a charging start voltage value included in the charging start state information with a charging end voltage value included in the charging end state information, and based on a state in which the voltage change value is greater than or equal to a second threshold occurring less than a specified number of times, measuring the degradation level of the battery by activating a constant current function for a specified time.

According to an embodiment, the instructions may cause the electronic device to identify a reduction in the battery's lifespan, based on the state in which the voltage change value is greater than or equal to the second threshold occurring the specified number of times, store information related to the battery's lifespan in the memory, and control the communication circuitry to transmit the information to at least one of the first external electronic device and the second external electronic device.

According to an embodiment, the compensation operation may be performed by setting a first compensation operation, not including compensation information, corresponding to a first degradation level among the degradation levels, setting a second compensation operation, including first compensation information, corresponding to a second degradation level among the degradation levels, and setting a third compensation operation, including second compensation information, corresponding to a third degradation level among the degradation levels.

According to an embodiment, the first compensation information may include a first full-charge condition margin value (e.g., approximately +30 mV).

According to an embodiment, the second compensation information may include a second full-charge condition margin value (e.g., approximately +50 mV) and a first voltage value (e.g., approximately −0.1 V) for full-charge voltage drop.

According to an embodiment, the charging start state information may include at least one of a voltage, a current, a state of charge (SOC), or a temperature at the start of charging the battery.

According to an embodiment, the charging end state information may include at least one of a voltage, a current, a state of charge, or a temperature at the end of charging the battery.

According to an embodiment, the instructions may cause the electronic device t refrain from performing wireless communication with the second external electronic device (e.g., the electronic device 101 in FIG. 1 and the second external electronic device 101 in FIG. 2C) while the battery is being charged by the first external electronic device, based on the electronic device being accommodated in the accommodation space inside the first housing of the first external electronic device and the second housing being closed.

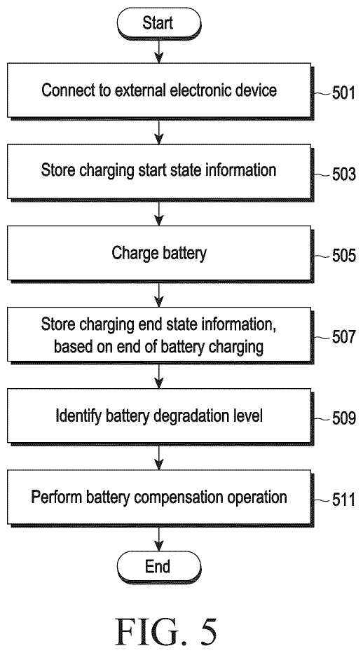

FIG. 5 is a flowchart illustrating an example of an operation method in an electronic device, according to an embodiment. In the following embodiment, operations may be performed sequentially, but the operations are not necessarily performed sequentially. For example, the order of the operations may be changed, and at least two operations may be performed in parallel.

Referring to FIG. 5, in operation 501, an electronic device (e.g., the electronic device 201 in FIGS. 2A, 2C, and 3), according to an embodiment, may be connected to a first external electronic device (e.g., the first external electronic device 203 in FIGS. 2A and 2B) via a wireless communication method (e.g., a Bluetooth™ communication method). The electronic device may be accommodated in the first external electronic device, which is an accommodation device such as a cradle, for charging and/or storage.

In operation 503, the electronic device may start battery charging, obtain charging start state information, and store the obtained charging start information in memory (e.g., the memory 330 in FIG. 3). The charging start state information may include at least one of a battery's voltage, current, SOC, or temperature. In a state in which the electronic device is accommodated in the first external electronic device, when the first external electronic device is in a closed state (e.g., a shielded state) as one surface of a second housing (e.g., the second housing 220 in FIG. 2A) of the first external electronic device rotates in a direction close to one surface of a first housing (e.g., the first housing 210 in FIG. 2A) and is closed, the electronic device may perform charging. When the first external electronic device is in an open state as the one surface of the second housing rotates in a direction away from the one surface of the first housing and is opened, the electronic device may not perform charging.

In operation 505, the electronic device may perform battery charging.

In operation 507, the electronic device may obtain charging end state information, based on the battery charging being ended (e.g., stopped or fully charged), and store the obtained charging end state information in the memory. The charging end state information may include at least one of a battery's voltage, current, SOC, or temperature.

In operation 509, the electronic device may perform, based on the charging start state information and the charging end state information stored in the memory, a degradation level measurement operation for identifying the battery degradation level. According to an embodiment, when performing the degradation level measurement operation, the electronic device may identify a battery state and transmit battery state information related to the identified battery state to the first external electronic device or a second external electronic device (e.g., the electronic device 101 in FIG. 1 and the electronic device 101 in FIG. 2C). The first external electronic device or the second external electronic device may display notification information configured based on the received battery state information on a display. The electronic device may be seated in the first external electronic device and wake up at the time of non-use after a full charge or at a specific interval (e.g., the t3-t4 time point in FIG. 4) to measure the degradation level by using a degradation level measurement algorithm for a specified time (e.g., approximately 5 to 10 seconds).

In operation 511, the electronic device may set compensation operations of the compensation algorithm according to the identified degradation level. The electronic device may compensate a charging table by using the compensation algorithm employing the set compensation operations and perform a compensation operation for battery protection and capacity (e.g., voltage) compensation.

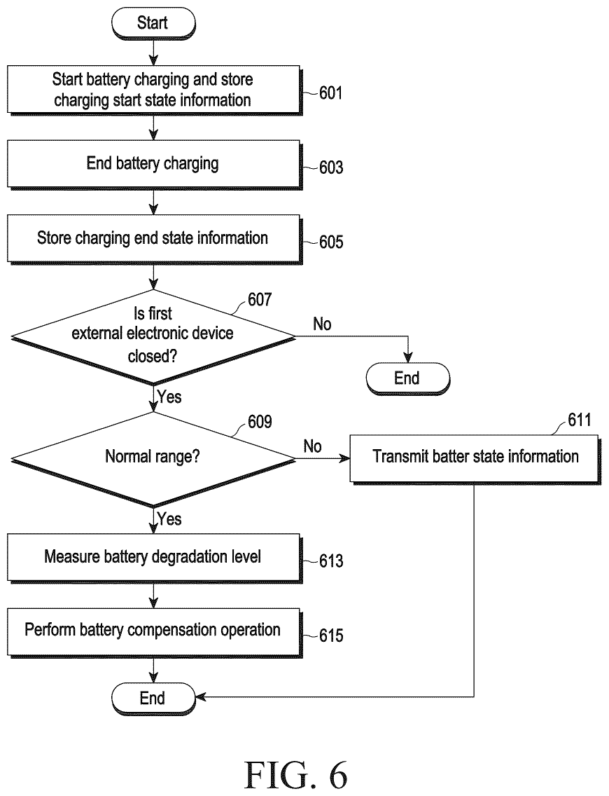

FIG. 6 illustrates an example of an operation method in an electronic device, according to an embodiment. In the following embodiments, operations may be performed sequentially, but the operations are not necessarily performed sequentially. For example, the order of the operations may be changed, and at least two operations may be performed in parallel.

Referring to FIG. 6, an electronic device (e.g., the electronic device 201 in FIGS. 2A, 2C, and 3), according to an embodiment, may, in operation 601, start battery charging, obtain charging start state information, and store the obtained charging start state information in memory (e.g., the memory 330 in FIG. 3). Here, the charging start state information may include at least one of the voltage, current, SOC, or temperature of a battery (e.g., the battery 321 in FIG. 3).

In operation 603, the electronic device may identify the end of the battery charging (e.g., stop or full charge). In operation 605, the electronic device may obtain charging end state information and may store the obtained charging end information in the memory. The charging end state information may include at least one of the battery's voltage, current, SOC, or temperature. The electronic device may store a pre-charger-off voltage (e.g., approximately 4.13 V) and a post-charger-off voltage (e.g., approximately 4.07 V) in memory.

In operation 607, the electronic device may identify whether a first external electronic device (e.g., the first external electronic device 203 in FIGS. 2A and 2B) is in a closed state (e.g., a shielded state) as a second housing (e.g., the second housing 220 in FIG. 2A) of the first external electronic device rotates in a direction in which one surface of the second housing approaches one surface of a first housing (e.g., the first housing 210 in FIG. 2A), and is thus closed. As a result of the identification, when the first external electronic device is in the closed state (Yes in operation 607), the electronic device performs operation 609. Otherwise, when the first external electronic device is in an open state as the second housing rotates in a direction in which the one surface thereof is away from the one surface of the first housing (e.g., the first housing 210 in FIG. 2A), and is thus opened (No in operation 607), the electronic device may end operation without performing a battery degradation level measurement operation.

In operation 609, after the battery charging is ended, the electronic device may identify whether the battery state falls within a normal range, based on the charging start state information and the charging end state information stored in memory. When the identification result indicates that the battery state is outside the normal range (No in operation 609), the electronic device may perform operation 611. When the battery state is within the normal range (Yes in operation 609), the electronic device may perform operation 613.

In operation 611, the electronic device may transmit battery state information indicating a risk of battery damage (e.g., defect or breakage) to at least one of the first external electronic device or a second external electronic device (e.g., the electronic device 101 in FIG. 1 or the second external electronic device 101 in FIG. 2C). According to an embodiment, the electronic device may obtain a temperature change value (e.g., the delta value between a temperature value at the start of charging and a temperature value at the end of CC1 (e.g., a time point at which the temperature is highest during charging)) by comparing a charging start temperature value included in the charging start state information with a charging end temperature value included in the charging end state information. When a state in which the temperature change value is greater than or equal to a first threshold (e.g., a first state) occurs a specified number of times (e.g., three times), the electronic device determines that the battery state is outside the normal range (e.g., an abnormal battery state due to damage or reduced lifespan), and may then lower the full-charge voltage of the battery 321 to a specified value (e.g., approximately −0.2 V) and transmit battery state information. When the state in which the temperature change value is greater than or equal to the first threshold occurs less than the specified number of times (e.g., three times), the electronic device may compare a charging start voltage value included in the charging start state information with a charging end voltage value included in the charging end state information to obtain a voltage change value (e.g., a delta (Δ) value between pre-full-charge and post-full-charge voltage values). When a state in which the voltage change value is greater than or equal to the second threshold occurs a specified number of times (e.g., three times), the electronic device may identify that the battery lifespan has been reduced and may transmit battery state information.

In operation 613, the electronic device may measure the actual degradation level of the battery through a constant current discharge operation, based on the battery state being within the normal range. The degradation level measurement may be performed once or two or more times. When the state in which the temperature change value is greater than or equal to the first threshold (e.g., the first state) occurs less than the specified number of times, and when the state in which the voltage change value is greater than or equal to the second threshold (e.g., a second state) occurs less than the specified number of times, the electronic device may measure the actual degradation level of the battery through a constant current discharge operation (e.g., the constant current discharge operation in the t3-t4 interval (measurement interval) in FIG. 4). When the degradation level is within the normal range (e.g., a range not identified as the time for battery replacement due to battery damage or reduced battery lifespan), the electronic device may activate (turn on) a constant current function (e.g., an LED) for a specified time (e.g., approximately 5 seconds) by using the constant current discharge operation to measure the actual degradation level of the battery caused by the constant current function. The electronic device may identify the actual degradation level by identifying the consumption current within the normal range through constant current discharge operation. Since accurate measurement is difficult during battery charging due to the operation of other specific functions, the constant current discharge operation may be performed when the electronic device is not in use after battery charging is ended.

In operation 615, the electronic device may set compensation operations for battery degradation compensation corresponding to each of the degradation level obtained by the battery degradation level measurement operation. The processor 310 may perform compensation for the resistance and voltage drop of the battery 321 according to the set compensation operations corresponding to the obtained degradation levels. The processor 310 may set a first compensation operation not including compensation information, based on the degradation level being a first degradation level. The processor 310 may set a second compensation operation including first compensation information, based on the degradation level being a second degradation level (e.g., a level at which the electronic device 201 may be used without abnormality at a set full-charge voltage). The first compensation information may include a first full-charge condition margin value (e.g., approximately +30 mV). The processor 310 may set a third compensation operation including second compensation information, based on the degradation level being a third degradation level (e.g., a level sufficient to cause damage to the battery). The second compensation information may include a second full-charge condition margin value (e.g., approximately +50 mV) and a first voltage value (e.g., approximately −0.1 V) for full-charge voltage drop.

According to an embodiment, the electronic device may perform a battery compensation operation by using a compensation algorithm (e.g., a long-life algorithm) that employs the set compensation operations. For example, the electronic device may identify a degradation level, based on charging state information measured during charging or auxiliary charging of the battery. When the identified degradation level is the first degradation level, the electronic device may apply the first compensation operation. Since the first compensation operation does not include a compensation value, the electronic device may not compensate for the degradation (e.g., capacity) of the battery when the degradation level is the first degradation level. For example, when the identified degradation level is the second degradation level, the electronic device may compensate for the degradation (e.g., capacity) of the battery 321 by applying the first full-charge condition margin value (e.g., +30 mV) included in the second compensation operation. For example, when the identified degradation level is the third degradation level, the electronic device may compensate for the degradation (e.g., capacity) of the battery 321 by applying the second full-charge condition margin value (e.g., +50 mV) included in the third compensation operation and lowering the full-charge voltage to the first voltage value (e.g., −0.1 V).

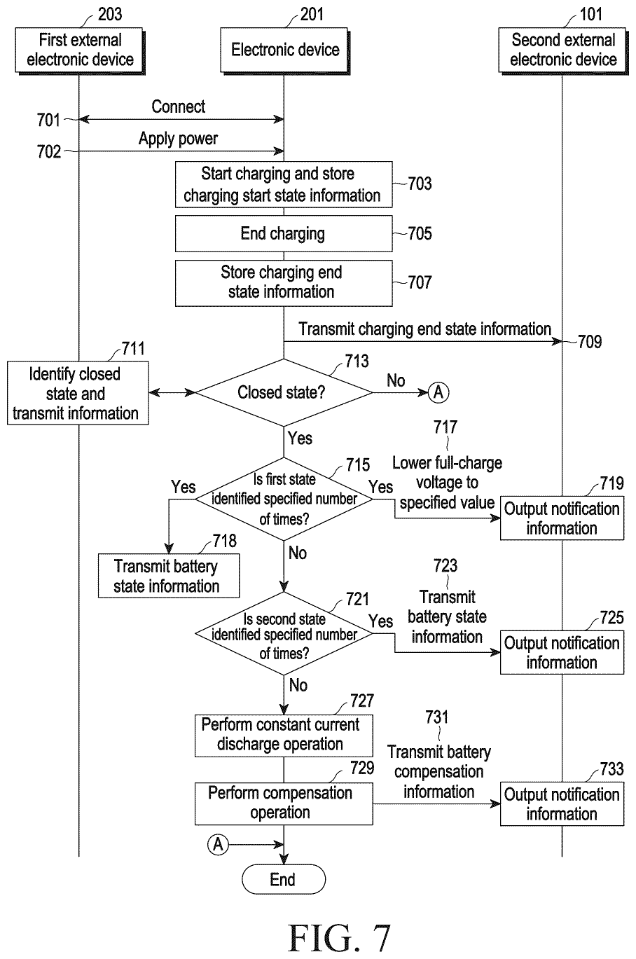

FIG. 7 is a diagram illustrating an example of the operation method of an electronic device and external electronic devices, according to an embodiment. In the following embodiment, operations may be performed sequentially, but the operations are not necessarily performed sequentially. For example, the order of the operations may be changed, and at least two operations may be performed in parallel.

Referring to FIG. 7, in operation 701, an electronic device (e.g., the electronic device 201 in FIGS. 2A, 2B, and 3), according to an embodiment, may be accommodated in a first external electronic device 203 (e.g., the first external electronic device 203 in FIGS. 2A and 2B) and may be connected to the first external electronic device 203 via a wireless communication method. In operation 702, the first external electronic device 203 may apply power to the electronic device 201. In this case, the first external electronic device 203 may be in a closed state while accommodating the electronic device 201.

In operation 703, the electronic device 201 may start charging of a battery by using the power applied from the first external electronic device 203 and may store charging start state information obtained at the start time point in memory.

In operation 705, the electronic device 201 may identify the end of the battery charging. In operation 707, when the battery charging ends, the electronic device 201 may store charging end state information.

In operation 709, the electronic device 201 may establish a communication connection with a second external electronic device 101 and then transmit the charging end state information. According to an embodiment, the electronic device 201 may transmit the charging end state information to the first external electronic device 203. When the first external electronic device 203 includes a display (e.g., the display 221 in FIG. 2A), the first external electronic device 203 may output the received charging end state information.

In operation 711, the first external electronic device 203 may identify whether the same is in a closed state or an open state, and may transmit information related to the identified open or closed state to the electronic device 201.

In operation 713, the electronic device 201 may receive information related to the open or closed state of the first external electronic device 203 to determine whether the first external electronic device 203 is in the closed state. As a result of the identification, open state information is received from the first external electronic device 203 (No in operation 713), the electronic device 201 may end the operation without setting a battery degradation level measurement operation or a compensation operation. When the closed state is identified (Yes in operation 713), the electronic device 201 may perform the battery degradation level measurement operation in subsequent operations (operations 715 to 721).

In operation 715, the electronic device 201 may determine whether a first state (e.g., a state in which the temperature change value is greater than or equal to a first threshold) is identified a specified number of times (e.g., three times). Here, the state in which the temperature change value is greater than or equal to the first threshold may be, for example, a state in which the delta is 10 degrees. According to an embodiment, the electronic device may obtain a temperature change value (e.g., the delta (delta Temp) value between a temperature value at the start of charging and a temperature value at the end of CC1 (e.g., a time point at which the temperature is highest during charging)) by comparing a charging start temperature value included in the charging start state information with a charging end temperature value included in the charging end state information.

As a result of the determination in operation 715 (Yes in operation 715), when the first state (e.g., the state in which the temperature change value is greater than or equal to the first threshold) is identified the specified number of times (e.g., three times), the electronic device 201 may identify, in operation 717, that the battery state is outside a normal range, lower the full-charge voltage of the battery 321 to a specified value (e.g., approximately −0.2 V), and transmit battery state information to the second external electronic device 101. Here, the battery state information may include information indicating a currently identified degradation stage value of the battery, and may additionally include voltage values or temperature values before and after the degradation level measurement. The electronic device 201 may set degradation stages (e.g., levels or operations) for charge capacity levels. For example, when a degradation stage where the charge capacity level is 75% or lower is identified, the electronic device 201 may identify that battery replacement is required. The second external electronic device 101 may identify the current state of the battery, based on the received battery state information, or may transmit the received battery state information to a server. In operation 719, the second external electronic device 101 may output notification information (e.g., “Visit a service center to have the battery inspected”) configured based on the received battery state information. The notification information has been described as being configured by the second external electronic device 101, but notification information may be configured by the electronic device 201 and transmitted to the first external electronic device 203 and/or the second external electronic device 101, either as part of the battery state information or separately. According to an embodiment, the electronic device 201 may transmit the battery state information to the first external electronic device 203. When the first external electronic device 203 includes a display, the first external electronic device 203 may output the notification information (e.g., “Visit a service center to have the battery inspected”) configured based on the battery state information. For example, when the first external electronic device 203 does not include a display, the first external electronic device 203 may provide a notification of the risk of battery damage through sound or light via another output interface, such as an audio module or a light-emitting element, based on the received battery state information.

As a result of the determination in operation 715 (No in operation 715), when the first state (e.g., the state in which the temperature change value is greater than or equal to the first threshold) occurs less than the specified number of times, the electronic device 201 may determine, in operation 721, whether a state in which a voltage change value is greater than or equal to a second threshold (e.g., a second state) is identified a specified number of times (e.g., three times). The electronic device 201 may obtain the voltage change value (e.g., the delta value between pre-full-charge and post-full-charge voltage values) by comparing a charging start voltage value included in the charging start state information with a charging end voltage value included in the charging end state information.

As a result of the determination in operation 721 (Yes in operation 721), when the state in which the voltage change value is greater than or equal to the second threshold occurs the specified number of times, the electronic device 201 may, in operation 723, identify that the battery lifespan has reduced and transmit battery state information to the second external electronic device 101. The battery state information may include information indicating the currently identified degradation stage value of the battery, and may additionally include voltage values or temperature values before and after the degradation level measurement. The electronic device 201 may set degradation stages (e.g., levels or operations) according to charge capacity levels. For example, when a degradation stage where the charge capacity level is 75% or lower is identified, the electronic device 201 may identify that battery replacement is required. The electronic device 201 may obtain information related to a battery lifespan identified based on the battery degradation level measurement operation and transmit battery state information, including the obtained battery lifespan information, to the second external electronic device 101. In operation 725, the second external electronic device 101 may output notification information (e.g., “Visit a service center to have the battery inspected”) configured based on the received battery state information. According to an embodiment, the electronic device 201 may transmit the battery state information to the first external electronic device 203. When the first external electronic device 203 includes a display, the first external electronic device 203 may output the notification information (e.g., “Visit a service center to have the battery inspected”) configured based on the battery state information. For example, when the first external electronic device 203 does not include a display, the first external electronic device 203 may provide a notification of the risk of battery damage through sound or light via another output interface such as an audio module or a light-emitting element, based on the received battery state information. When the battery state information including battery lifespan-related information is received from the electronic device 201, the first external electronic device 203 may transmit the received battery compensation information to another external electronic device (e.g., the second external electronic device 101 or the server).

As a result of the determination in operation 721 (No in operation 721), when the second state (e.g., the state in which the voltage change value is greater than or equal to the second threshold occurs less than the specified number of times (e.g., three times)), the electronic device 201 may measure, in operation 727, the actual degradation level of the battery through a constant current discharge operation. The electronic device may identify the degradation level as being within the normal range (e.g., a range not identified as the time for battery replacement due to battery damage or reduced battery lifespan), and may activate (turn on) a constant current function (e.g., an LED) for a specified time (e.g., 5 seconds) by using the constant current discharge operation to measure the actual degradation level of the battery 321 caused by the constant current function. The electronic device may identify the actual degradation level by identifying the consumption current within the normal range through the constant current discharge operation. Since accurate measurement is difficult during battery charging due to the operation of other specific functions, the constant current discharge operation may be performed when the electronic device is not in use after battery charging is ended.

In operation 729, the electronic device may perform a compensation operation to be applied during charging of the battery, based on information obtained through the battery degradation level measurement operation. According to an embodiment, the electronic device may set compensation operations for battery degradation compensation according to degradation levels obtained by the battery degradation level measurement operation. The electronic device may perform compensation for the resistance and voltage drop of the battery 321 according to the compensation operations set for the obtained degradation levels. The electronic device may set a first compensation operation not including compensation information, based on the degradation level being a first degradation level. The electronic device may set a second compensation operation including first compensation information, based on the degradation level being a second degradation level. The first compensation information may include a first full-charge condition margin value (e.g., +30 mV). The processor 310 may set a third compensation operation including second compensation information, based on the degradation level being a third degradation level. The second compensation information may include a second full-scale condition margin value (e.g., +50 mV) and a first voltage value (e.g., −0.1 V) for full-charge voltage drop.

In operation 731, the electronic device 201 may transmit battery compensation information, which includes information related to the set compensation operations, to the second external electronic device 101. In operation 733, the second external electronic device 101 may output notification information configured based on the received battery compensation information (e.g., display a battery life cycle and a compensation operation on a display). According to an embodiment, the electronic device 201 may transmit the battery compensation information, which includes information related to the set compensation operations, to the first external electronic device 203. The first external electronic device 203 may receive the battery compensation information from the electronic device 201. When the first external electronic device 203 includes a display, the first external electronic device 203 may display notification information configured based on the battery compensation information. When the battery compensation information is received from the electronic device 201, the first external electronic device 203 may transmit the received battery compensation information to another external electronic device (e.g., the second external electronic device 101 or the server).

According to an embodiment, an operation method in an electronic device (e.g., the electronic device 201 in FIGS. 2A, 2C, and 3) may include an operation of obtaining connection information indicating a connection with a first external electronic device (e.g., the first external electronic device 203 in FIGS. 2A and 2B) that provides power to charge a battery (e.g., the battery 321 in FIG. 3) of the electronic device.

According to an embodiment, the operation method may include an operation of obtaining charging start state information when charging of the battery is started with power applied from the first external electronic device and storing the charging start state information in memory (e.g., the memory 330 in FIG. 3) of the electronic device.

According to an embodiment, the operation method may include an operation of obtaining charging end state information, based on the end of charging of the battery, and storing the charging end state information in the memory.

According to an embodiment, the operation method may include an operation of identifying a battery state based on the charging start state information and the charging end state information, and an operation for performing a battery degradation level measurement operation based on information about the identified battery state.

According to an embodiment, the operation method may include an operation of performing, based on information obtained by the battery degradation level measurement operation, a compensation operation for compensating for the battery's degradation, the compensation operation corresponding to each degradation level and being to be applied during charging of the battery.

According to an embodiment, in the operation method, the electronic device may include an earbud, and the first external electronic device may include a case including an accommodation space (e.g., the accommodation space 211 in FIG. 2A) for storing the earbud, and a battery in the case.

According to an embodiment, the operation method may further include an operation of identifying the earbud accommodated in the accommodation space inside the case, and an operation of measuring the degradation level of the battery, based on the electronic device being accommodated in the accommodation space inside a first housing (e.g., the first housing 210 in FIG. 2A) of the case and a second housing (e.g., the second housing 220 in FIG. 2A) being closed with respect to the first housing.

According to an embodiment, the operation of performing the battery degradation level measurement may be performed based on at least one of a temperature change value, a voltage change value, or a constant current discharge operation. The method may further include an operation of stopping the battery degradation level measurement, based on the earbud being accommodated in the accommodation space inside the first housing of the case and the second housing being opened with respect to the first housing.

According to an embodiment, the operation of performing the battery degradation level measurement may include an operation of obtaining a temperature change value by comparing a charging start temperature value included in the charging start state information with a charging end temperature value included in the charging end state information. According to an embodiment, the compensation operation may include an operation of lowering the battery's full-charge voltage to a specified value (−0.2 V), based on a state in which the temperature change value is greater than or equal to a first threshold occurring a specified number of times (e.g., three times).

According to an embodiment, the method may include an operation of transmitting notification information for notifying of the risk related to the battery to at least one of the first external electronic device or a second external electronic device via communication circuitry (e.g., the communication module 340 in FIG. 3) of the electronic device, based on the state in which the temperature change value is greater than or equal to the first threshold occurring the specified number of times.

According to an embodiment, the operation of performing the battery degradation level measurement may include an operation of obtaining a voltage change value by comparing a charging start voltage value included in the charging start state information with a charging end voltage value included in the charging end state information, based on the state in which the temperature change value is greater than or equal to the first threshold occurring less than the specified number of times, and an operation of performing the constant current discharge operation by activating a constant current function for a specified time, based on a state in which the voltage change value is greater than or equal to a second threshold occurring less than a specified number of times.

According to an embodiment, the battery degradation level measurement operation may further include an operation of identifying a reduction in the battery's lifespan, based on the state in which the voltage change value is greater than or equal to the second threshold occurring the specified number of times, and an operation of storing information related to the battery's lifespan in the memory and transmitting the information to at least one of the first external electronic device and the second external electronic device via the communication circuit.

According to an embodiment, the compensation operation may include an operation of setting a first compensation operation, not including compensation information, corresponding to a first degradation level among the degradation levels, an operation of setting a second compensation operation, including first compensation information, corresponding to a second degradation level among the degradation levels, and an operation of setting a third compensation operation, including second compensation information, corresponding to a third degradation level among the degradation levels. According to an embodiment, the first compensation information may include a first full-charge condition margin value (e.g., +30 mV). According to an embodiment, the second compensation information may include a second full-charge condition margin value (e.g., +50 mV) and a first voltage value (e.g., −0.1 V) for full-charge voltage drop.

According to an embodiment, the charging start state information may include at least one of a voltage, a current, a state of charge (SOC), or a temperature at the start of charging the battery. According to an embodiment, the charging end state information may include at least one of a voltage, a current, a state of charge, or a temperature at the end of charging the battery.

According to an embodiment, in a non-transitory storage medium storing one or more programs, the one or more programs may include commands which, when executed by at least one processor (e.g., the processor 310 in FIG. 3) of an electronic device (e.g., the electronic device 201 in FIGS. 2A, 2C, and 3), cause the electronic device to perform an operation of obtaining connection information indicating a connection with a first external electronic device (e.g., the first external electronic device 203 in FIGS. 2A and 2B) that provides power to charge a battery (e.g., the battery 321 in FIG. 3) of the electronic device, an operation of obtaining charging start state information when charging of the battery is started with the power applied from the first external electronic device, and storing the charging start state information in memory (e.g., the memory 330 in FIG. 3) of the electronic device, an operation of obtaining charging end state information, based on the end of charging of the battery, and storing the charging end state information in the memory, an operation of identifying a battery state, based on the charging start state information and the charging end state information, an operation of performing a battery degradation level measurement operation, based on information about the identified battery state, and an operation of performing, based on the information obtained by the battery degradation level measurement operation, a compensation operation to be applied during charging of the battery.

According to an embodiment of the disclosure, the electronic device may measure the actual degradation level of a battery, reflecting not only a charge-discharge cycle while the battery is in use but also the degradation level based on the storage environment, by actually measuring various state values of the battery, rather than simply monitoring the current state of the battery in real time. The electronic device may apply a compensation algorithm based on the measured actual degradation results to enhance usability, establish countermeasures for related VoC (e.g., rapid discharge, reduced usage time), convert degradation related to usage patterns into big data, and manage battery lifespan. The electronic device may notify a user of battery lifespan information and replacement cycles from a user experience (UX) perspective, thereby preventing battery damage incidents. Additionally, various effects directly or indirectly discernible herein may be provided. The effects obtainable from the disclosure are not limited to those mentioned above, and other effects not mentioned are to be clearly understood by those skilled in the art from the following description.

The embodiments disclosed herein are presented for the purpose of describing and understanding the disclosed technical content and do not limit the scope of the technology described herein. Therefore, the scope of this document should be interpreted as including all modifications or various other embodiments based on the technical idea of this document.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
a battery;
communication circuitry;
at least one processor; and
memory storing instructions,
wherein the instructions, when executed by the at least one processor individually or collectively, cause the electronic device to:
obtain connection information indicating a connection with a first external electronic device that provides power to charge the battery,
based on charging of the battery being started with the power applied from the first external electronic device, obtain charging start state information and store the charging start state information in the memory,
based on the charging of the battery reaching an end state, obtain charging end state information and store the charging end state information in the memory,
identify, based on the charging start state information and the charging end state information, a state of the battery,
perform, based on the state of the battery, a battery degradation level measurement operation, and
perform, based on a result of the battery degradation level measurement operation, a compensation operation during charging of the battery.

2. The electronic device of claim 1, further comprising:
an earbud,
wherein the instructions, when executed by the at least one processor individually or collectively, further cause the electronic device to:
determine whether the earbud is accommodated in an accommodation space of the first external electronic device; and
perform, based on a determination that the earbud is accommodated in the accommodation space inside a first housing of the first external electronic device and a second housing of the first external electronic device is closed with respect to the first housing, the battery degradation level measurement operation.

3. The electronic device of claim 2, wherein the instructions, when executed by the at least one processor individually or collectively, further cause the electronic device to:
perform, based on at least one of a temperature change value, a voltage change value, or a constant current discharge operation, the battery degradation level measurement operation;
based on a determination that the earbud is accommodated in the accommodation space inside the first housing and the second housing is open with respect to the first housing, stop performing the battery degradation level measurement operation;
perform the battery degradation level measurement operation by obtaining the temperature change value by comparing a charging start temperature value indicated by the charging start state information and a charging end temperature value indicated by the charging end state information; and
perform, based on the temperature change value being greater than or equal to a first threshold value occurring a specified number of times, the compensation operation by lowering a full charge voltage level of the battery to a specified value.

4. The electronic device of claim 3, wherein the instructions, when executed by the at least one processor individually or collectively, further cause the electronic device to:
transmit, using the communication circuitry to at least one of the first external electronic device or a second external electronic device, notification information notifying a risk associated with the battery, based on the temperature change value being greater than or equal to the first threshold value occurring the specified number of times.

5. The electronic device of claim 4, wherein the instructions, when executed by the at least one processor individually or collectively, further cause the electronic device to:
obtain, based on the temperature change value being greater than or equal to the first threshold value occurring less than the specified number of times, the voltage change value by comparing a charging start voltage value indicated by the charging start state information and a charging end voltage value indicated by the charging end state information; and
perform, based on the voltage change value being greater than or equal to a second threshold value occurring less than the specified number of times, the constant current discharge operation by activating a constant current function for a specified time duration.

6. The electronic device of claim 5, wherein the instructions, when executed by the at least one processor individually or collectively, further cause the electronic device to:
identify, based on the voltage change value being greater than or equal to the second threshold value occurring the specified number of times, degradation of a life of the battery;
store, in the memory, information related to the life of the battery; and
transmit, using the communication circuitry to the at least one of the first external electronic device or the second external electronic device, the information related to the life of the battery.

7. The electronic device of claim 6, wherein the instructions, when executed by the at least one processor individually or collectively, further cause the electronic device to:
set a first compensation operation, excluding compensation information, corresponding to a first degradation level from among a plurality of degradation levels;
set a second compensation operation, comprising first compensation information, corresponding to a second degradation level from among the plurality of degradation levels; and
set a third compensation operation, comprising second compensation information, corresponding to a third degradation level from among the plurality of degradation levels,
wherein the first compensation information comprises a first full charging condition margin value,
wherein the second compensation information comprises a second full charging condition margin value and a first voltage value for a full charging voltage drop,
wherein the charging start state information comprises at least one of a start voltage, a start current, a start charging state, or a start temperature measured at a first time when the charging of the battery is being started, and
wherein the charging end state information comprises at least one of an ending voltage, an ending current, an ending state of charge, or an ending temperature measured at a second time when the charging of the battery reaches the end state.

8. An operation method of an electronic device, the operation method comprising:
obtaining connection information indicating a connection with a first external electronic device that provides power to charge a battery of the electronic device;
based on charging of the battery being started with the power applied from the first external electronic device, obtaining charging start state information and storing the charging start state information in a memory of the electronic device;
based on the charging of the battery reaching an end state, obtaining charging end state information and storing the charging end state information in the memory;
identifying, based on the charging start state information and the charging end state information, a battery state;
performing, based on the battery state, a battery degradation level measurement; and
performing, based on a result of the battery degradation level measurement, a compensation operation during charging of the battery.

9. The operation method of claim 8, further comprising:
determining whether an earbud of the electronic device is accommodated in an accommodation space of the first external electronic device; and
measuring, based on determining that the earbud is accommodated in the accommodation space inside a first housing of the first external electronic device and a second housing of the first external electronic device is closed with respect to the first housing, a degradation level of the battery.

10. The operation method of claim 9, wherein the measuring of the degradation level of the battery comprises:
measuring the degradation level of the battery based on at least one of a temperature change value, a voltage change value, or a constant current discharge operation, and
wherein the operation method further comprises:
based on determining that the earbud is accommodated in the accommodation space inside the first housing of the first external electronic device and the second housing is open with respect to the first housing, stopping the measuring of the degradation level of the battery.

11. The operation method of claim 10, wherein the measuring of the degradation level of the battery comprises:
obtaining the temperature change value by comparing a charging start temperature value indicated by the charging start state information with a charging end temperature value indicated by the charging end state information, and
wherein the compensation operation comprises:
based on determining that the temperature change value is greater than or equal to a first threshold occurring a specified number of times, lowering a full-charge voltage of the battery to a specified value.

12. The operation method of claim 11, further comprising:
transmitting, to at least one of the first external electronic device or a second external electronic device via communication circuitry of the electronic device, notification information notifying of a risk related to the battery, based on determining that the temperature change value is greater than or equal to the first threshold occurring the specified number of times.

13. The operation method of claim 12, wherein the measuring of the degradation level of the battery comprises:
based on determining that the temperature change value is greater than or equal to the first threshold occurring less than the specified number of times, obtaining the voltage change value by comparing a charging start voltage value indicated by the charging start state information with a charging end voltage value indicated by the charging end state information;
based on determining that the voltage change value is greater than or equal to a second threshold occurring less than the specified number of times, performing the constant current discharge operation by activating a constant current function for a specified time duration;
based on determining that the voltage change value is greater than or equal to the second threshold occurring the specified number of times, identifying a reduction in a lifespan of the battery;
storing information related to the lifespan of the battery in the memory; and
transmitting, to at least one of the first external electronic device and the second external electronic device via the communication circuitry, the information related to the lifespan of the battery.

14. The operation method of claim 13, wherein the compensation operation comprises:
setting a first compensation operation, excluding compensation information, corresponding to a first degradation level from among a plurality of degradation levels;
setting a second compensation operation, comprising first compensation information, corresponding to a second degradation level from among the plurality of degradation levels; and
setting a third compensation operation, comprising second compensation information, corresponding to a third degradation level from among the plurality of degradation levels,
wherein the first compensation information comprises a first full-charge condition margin value,
wherein the second compensation information comprises a second full-charge condition margin value and a first voltage value for a full-charge voltage drop,
wherein the charging start state information comprises at least one of a starting voltage, a starting current, a starting state of charge, or a starting temperature measured at a first time when the charging of the battery is being started, and
wherein the charging end state information comprises at least one of an ending voltage, an ending current, an ending state of charge, or an ending temperature measured at a second time when the charging the battery reaches the end state.

15. A non-transitory storage medium storing one or more programs, wherein the one or more programs comprise instructions that, when executed by at least one processor of an electronic device, cause the electronic device to perform:
obtaining connection information indicating a connection with a first external electronic device that provides power to charge a battery of the electronic device;
based on charging of the battery being started with the power applied from the first external electronic device, obtaining charging start state information and storing the charging start state information in memory of the electronic device;
based on the charging of the battery reaching an end state, obtaining charging end state information and storing the charging end state information in the memory;
identifying, based on the charging start state information and the charging end state information, a battery state;
performing, based on the battery state, a battery degradation level measurement; and
performing, based on a result of the battery degradation level measurement, a compensation operation during charging of the battery.

16. The non-transitory storage medium of claim 15, wherein the instructions, when executed by the at least one processor, further cause the electronic device to:
determining whether an earbud of the electronic device is accommodated in an accommodation space of the first external electronic device; and
measuring, based on determining that the earbud is accommodated in the accommodation space inside a first housing of the first external electronic device and a second housing of the first external electronic device is closed with respect to the first housing, a degradation level of the battery.

17. The non-transitory storage medium of claim 16, wherein the instructions, when executed by the at least one processor, further cause the electronic device to:
measuring the degradation level of the battery based on at least one of a temperature change value, a voltage change value, or a constant current discharge operation; and
based on determining that the earbud is accommodated in the accommodation space inside the first housing of the first external electronic device and the second housing is open with respect to the first housing, stopping the measuring of the degradation level of the battery.

18. The non-transitory storage medium of claim 17, wherein the instructions, when executed by the at least one processor, further cause the electronic device to:
obtaining the temperature change value by comparing a charging start temperature value indicated by the charging start state information with a charging end temperature value indicated by the charging end state information; and
based on determining that the temperature change value is greater than or equal to a first threshold occurring a specified number of times, lowering a full-charge voltage of the battery to a specified value.

19. The non-transitory storage medium of claim 18, wherein the instructions, when executed by the at least one processor, further cause the electronic device to:
transmitting, to at least one of the first external electronic device or a second external electronic device via communication circuitry of the electronic device, notification information notifying of a risk related to the battery, based on determining that the temperature change value is greater than or equal to the first threshold occurring the specified number of times.

20. The non-transitory storage medium of claim 19, wherein the instructions, when executed by the at least one processor, further cause the electronic device to:
based on determining that the temperature change value is greater than or equal to the first threshold occurring less than the specified number of times, obtaining the voltage change value by comparing a charging start voltage value indicated by the charging start state information with a charging end voltage value indicated by the charging end state information;
based on determining that the voltage change value is greater than or equal to a second threshold occurring less than the specified number of times, performing the constant current discharge operation by activating a constant current function for a specified time duration;
based on determining that the voltage change value is greater than or equal to the second threshold occurring the specified number of times, identifying a reduction in a lifespan of the battery;
storing information related to the lifespan of the battery in the memory; and
transmitting, to at least one of the first external electronic device and the second external electronic device via the communication circuitry, the information related to the lifespan of the battery.
